(19) United States
(12) Patent Application Publication
(10) Pub. No.: US 2025/0328713 A1
(43) Pub. Date: Oct. 23, 2025

(54) METHOD FOR OBTAINING ENGINEERING CHANGE ORDER POINT BASED ON COMPARISON OF DESIGN FILES

(71) Applicant: Easy-Logic Technology (Shenzhen) Co., Ltd., Shenzhen (CN)

(72) Inventors: Xiao ZHANG, Shenzhen (CN); Xing WEI, Shenzhen (CN); Feng YUAN, Shenzhen (CN); Yi DIAO, Shenzhen (CN); Tak-Kei LAM, Shenzhen (CN); Xiaoqing YANG, Shenzhen (CN)

(21) Appl. No.: 18/659,350

(22) Filed: May 9, 2024

(30) Foreign Application Priority Data
Apr. 23, 2024 (CN) 202410491064.X

(51) Int. Cl. G06F 30/33

(52) U.S. Cl. CPC G06F 30/33

(57) ABSTRACT

The present application provides a method for obtaining an engineering change order (ECO) point based on a comparison of design files, for finding difference ECO points between a revision design and an original design in a chip design, the method includes finding an old GTECH file corresponding to the original design and a new GTECH file corresponding to the revision design; comparing the old GTECH file and the new GTECH file to find key point information; and based on the key point information, analyzing a component composition and connection of a circuit, to find the difference ECO points.

### CROSS-REFERENCE TO RELATED APPLICATIONS

The present application claims priority to Chinese Patent Application No. 202410491064.X, filed Apr. 23, 2024, the entire disclosure of which is incorporated herein by reference.

### TECHNICAL FIELD

The present application belongs to the technical field of integrated circuits, and specifically relates to a method for obtaining an ECO point based on a comparison of design files.

### BACKGROUND

In the field of integrated circuit (IC) design, the industry's mainstream method for extracting an engineering change order (ECO) point (i.e., the difference points between the revision chip design and the original design) is the comparison between the original netlist and the revision netlist, or the comparison between the original register transfer level (RTL) and the revision RTL. With the development of technology and the increase of the complexity of design, the industry is also continuously exploring new, more efficient method for extracting ECO point, for example, some advanced tools and methods may use formal verification techniques to compare the equivalence between two designs, or the ECO points are identified and extracted automatically through machine learning and artificial intelligence techniques. These methods can improve the accuracy and efficiency of extracting the ECO points, further reduce the effort of manual modifications, and accelerate the overall design flow. However, despite the emergence of new methods and techniques, primitive netlist comparison and RTL comparison are still the mainstream ECO point extraction methods in the industry.

Both methods use logic equivalence check (LEC) engine to globally compare the two input files. Mainstream LEC tools are commercial products, and the traditional method of using LEC tools must obtain commercial authorization, which has the problems of high cost and uncontrollable security.

In addition, netlist is the underlying representation of chip design, which contains a large number of gate-level and logic-level details. Comparing two netlists may generate a large number of difference points, many of which may be non-critical, resulting in engineers spending a great deal of time filtering and identifying the real ECO points; and the netlist comparison focuses mainly on the differences in the logical structure and connectivity relationships, but it often fails to reflect the high-level design intent and function. When facing complex design changes, it may be difficult to accurately understand the motivation of the changes by relying only on netlist comparison; and although RTL can reflect the design intent and function, it may hide some of the underlying implementation details compared to netlist, so that RTL comparison may not be able to reveal some of the ECO points that have been introduced in underlying implementations, and RTL changes usually need to be verified in detail in order to identify the true ECO points. RTL changes usually need to be verified in detail to ensure their correctness and consistency. Extracting ECO points based on RTL comparisons introduces additional verification work, which is time-consuming and labour-intensive, and it usually takes a few days to obtain the ECO points, and then if we find out that there is a problem with the ECO points at a later stage we have to start from scratch, which will take a few more days.

Therefore, it is an urgent problem in chip design to find a fast and accurate ECO acquisition method.

### SUMMARY

The purpose of the present application is to provide a method of obtaining ECO points based on the comparison of design files, which finds difference ECO points between the revision design and the original design in a chip design and obtains the ECO points by comparing the original GTECH and the revision GTECH, and this method needn't a commercial LEC tool. The present application aims at using GTECH to get ECO points, the specific technical solution is as follows:

In order to solve the above technical problems, the technical solution adopted in the present application is as follows.

A method for obtaining an engineering change order (ECO) point based on a comparison of design files, for finding difference ECO points between a revision design and an original design in a chip design, the method uses a generic technology (GTECH) file for comparison without using a logic equivalence check (LEC) tool;
the method includes:
Step S1, finding an old GTECH file corresponding to the original design and a new GTECH file corresponding to the revision design;
Step S2, comparing the old GTECH file and the new GTECH file to find key point information; and
Step S3, based on the key point information, analyzing a component composition of a circuit and connection of components in the circuit, to find the difference ECO points.

In an embodiment, in the step S2, the comparing the old GTECH file and the new GTECH file includes:
comparing based on a component and a logic, respectively, to find the key point information;
based on the component, analyzing structures of the old GTECH file and the new GTECH file, and finding types, numbers and connection relationships of components contained in the old GTECH file and the new GTECH file respectively;
comparing the type, number and connection relationship of each component in the old GTECH file and the new GTECH file to see whether they are changed, and when one thereof is not the same in the old GTECH file and the new GTECH file, then it is determined that the component is changed;
marking the changed component as the key point information; and
based on the logic, determining whether logical functionality implemented in the old GTECH file and the new GTECH file are consistent, marking a part of the logical functionality that is changed as the key point information.

In an embodiment, the key point information at least includes a key component added or deleted, a component whose parameter change affects timing or power consumption, and the part of the logical functionality that is changed.

In an embodiment, the comparing the type, number and connection relationship of each component in the old GTECH file and the new GTECH file to see whether they are changed includes:
determining whether the type of each component in the old GTECH file and the new GTECH file is the same, whether there are new or deleted types of components, or whether any types of components are replaced; and
determining whether the number of components of the same type in the old GTECH file and the new GTECH file are the same, wherein any increase or decrease in the number is considered to be a change.

In an embodiment, in the step S3, the analyzing the component composition of the circuit and connection of the component in the circuit includes:
comparing functions of the circuits of the original design and the revision design based on the key point information;
analyzing overall circuit architectures and functional description of the original design and the revision design;
comparing a connection relationship and a signal flow of each component in the original design and the revision design;
checking whether there are new or deleted component connections and changes in the connection relationships; and
marking the key point information where there are differences as the difference ECO points.

In an embodiment, the comparing a consistency of logical functionality implemented in the old GTECH file and the new GTECH file is to check whether the old GTECH file and the new GTECH file are functionally equivalent, at least comprising checks of the signal flow and interface compatibility;
the check of the signal flow refers to check whether a flow path of signals in the old GTECH file and the new GTECH file are the same, comprising a transmission, processing and output of the signals; and
the check of the interface compatibility refers to verify that interfaces in the old GTECH file and the new GTECH file are compatible to ensure that there are no problems with connections to other modules.

The beneficial effects of the present application compared with the related art are:

The present application is able to quickly locate the key points of the design changes by comparing the GTECH files of the original design and the revision design, thus avoiding comprehensively analyzing the whole design, and greatly improving the design efficiency; and overcomes the problem that the existing method of extracting the ECO points has to rely on a commercial LEC tool, which is costly, uncontrollable and slow.

### BRIEF DESCRIPTION OF THE DRAWINGS

FIG. 1 is a flowchart of a method of the present application for obtaining ECO points based on a comparison of design documents.

FIG. 2 is a diagram of the type of the gate changes in the same position according to the embodiment of the present application.

FIG. 3 is a diagram of different components and connections of two circuits which implement the same logic according to the embodiment of the present application.

### DETAILED DESCRIPTION OF THE EMBODIMENTS

In order to make the objects, technical solutions and advantages of the present application clearer, the technical solutions of the present application are described clearly and completely below, and it is obvious that the described embodiments are a part of the embodiments of the present application and not all of the embodiments.

It is to be noted that, based on the embodiments of the present application, all other embodiments obtained by those skilled in the art without making creative labour fall within the scope of the present application.

In chip design industry, the designer first has an RTL (register transfer level) for their chip design, which can be seen as the source code in programming. And then they will perform logic synthesis on the RTL to get synthesis netlist. Netlist is the document that describes the components of a chip circuit and their connections, whereas RTL describes the logical functionality of the chip circuit. And then the designers will add more components into the netlist and do many optimizations. Finally, they have to do placement (of the circuit components) and routing (of the circuit wires). It takes months to finish this process.

And if they have spent months to go through this process and find there are bugs in the RTL. They can only start all over again by tearing everything down. In this scenario ECO can kick in. ECO is an EDA software which can directly change the processed original netlist directly into the correct version corresponding to the new RTL.

In the existing technology, bugs in the original source code need to be found. However, instead of correcting the source code and compile the executable problem again, the present application directly adds a patch to the current executable problem to make it right, similar to how does the Microsoft update the windows.

So, to perform ECO, the present application needs to make clear what exactly the difference is (the difference between original and the new RTL). The difference is what does the present application want to change, and it is called ECO points.

The previous method compares old/new RTL or old/new GTECH to get the ECO points. It needs another EDA tool called LEC (logic equivalence check). However, the present application uses new/old GTECH comparison to extract ECO point and it doesn't need LEC tools, so that it can be done within 10 minutes, while related method takes hours.

When the existing method compares old/new RTL, the RTL describes functional logic of the circuit instead of intuitive circuit composition and connection relationships. Designers must use LEC tools to finish such a hard job and it takes times. When the existing method compares old/new netlist, Netlists are generated by synthesis tools after many iterations of optimization. The synthesis tools may use different optimization approaches when processing the old/new RTL, so that old/new netlist may have significant structural differences. Therefore, it is also hard to compare netlist.

The present application compares old/new GTECH. The GTECH is a special form of netlist generated in the synthesis process. The differences here is that GTECH doesn't go through any optimization and hence it is a semi-finished product that directly reflects the content of RTL without optimization.

It is netlist which consists of intuitive circuit composition and connection relationships. It also doesn't go through any optimization, so the old/new GTECH are so close to each other. The only differences are basically the ECO points. This is the reason why using GTECH to get ECO points has such advantages.

How does the present application process GTECH?
1. Doing key points mapping by using EasylogicECO.

The old/new GTECG are compared to find key points (Blackbox, Primary Inputs, Primary Output, DFF) and the key points are matched from the old/new GTECH. Since GTECH doesn't go through any optimization, the present application doesn't need to consider sequential optimization, like constant propagation, register merging, INV push in the process, and it massively increases the speed.
2. Comparing the circuit.

Since GTECH doesn't go through any optimization, the old and new GTECH have its most modules inside exactly the same. And hence the present application can use structural analysis instead of logical analysis to find the differences (ECO point). Structural analysis is much simpler than logical analysis, so that the present application needs no LEC, and it saves more time.

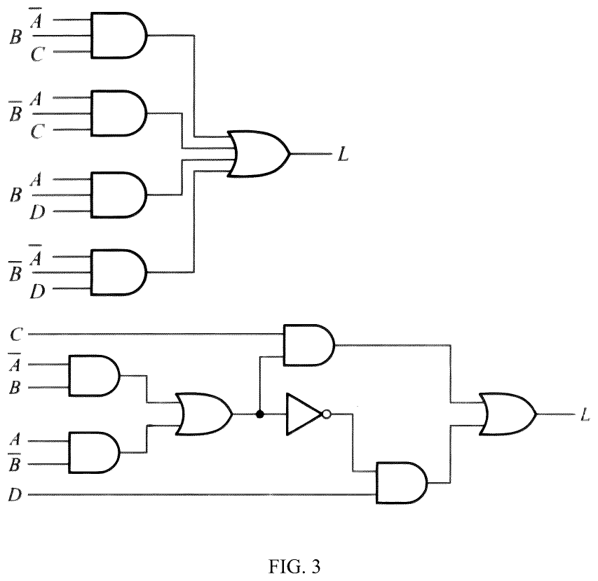

In the present application, the structural analysis is to directly compare the circuit components and connections, as shown in FIG. 2, the type of the gate changes in the same position. The logical analysis is that the components and connections of the circuit are totally different, but they implement the same logic. Logical analysis to find out their logical expressions and compare, as shown in FIG. 3, for example, two circuits are the same (implement the same logic) but they have completely different components and connects.

The logical expression:

L=(ĀB+AB̅)C+(AB+ĀB̅)D

The present application can use structural analysis instead of logical analysis in GTECH comparison, so it is much faster.

### Embodiments of the Present Application

This embodiment provides a method of obtaining an ECO point based on a comparison of design files, by comparing an old GTECH file of the original design and a new GTECH file of the revision design, to find a key point information; based on the key point information, to analyze the component composition of the circuit and connection of the component, to find a difference ECO point.

It should be noted that, usually, RTL (a kind of logical level to describe the function of the chip file) after the logic synthesis will generate synthesis netlist, but this embodiment uses a special netlist that is GTECH, GTECH is RTL->netlist, a very intuitive translation, without any optimization, its hierarchical structure and that of RTL basically correspond exactly to each other, and this kind of netlist is the netlist directly outputted after the elaboration in the logic synthesis process.

After the synthesis tool reads in the RTL code, the tool will first analyze the logical levels of the RTL code and the inputs and outputs between the different logical levels, and then the tool will map the RTL to the tool's own process libraries (GTECH Cells), and then directly output the GTECH netlist without compiling. The GTECH netlist still maintains the same hierarchical structure as the RTL code, and then the GTECH is compiled and optimized to get the synthesis netlist, which can be simplified as RTL->GTECH->synthesis netlist.

The traditional functional ECO method extracts ECO points by comparing RTL or netlist, while the embodiment uses GTECH to extract ECO points. Specifically, the old GTECH file of the original design is compared to the new GTECH file of the revision design, the structures of the old GTECH file and the new GTECH file of the revision design are analyzed to find out the types, parameters, attributes and connection relationships of the components contained therein, and the types, numbers, parameters, attributes and connection relationships of each components contained in two files are compared to see if they are changed, and the changed components are marked as the key point information.

Whether the logical functionality of the new GTECH file in the revision design is analyzed to be consistent with that of the old GTECH file in the original design, and the part of the logical functionality that is changed is marked as the key point information.

The key point information includes: new or deleted key components, components whose parameter changes affects the timing or power consumption, and a part of the logical functionality that is changed.

The analyzing component composition of the circuit and connection of the component includes: comparing functions of the circuits of the original design and the revision design based on the key point information; analyzing overall circuit architectures and functional description of the original design and the revision design; comparing a connection relationship and a signal flow of each component in the original design and the revision design; checking whether there are new or deleted component connections and changes in the connection relationships; and marking the key point information where there are differences as the difference ECO points.

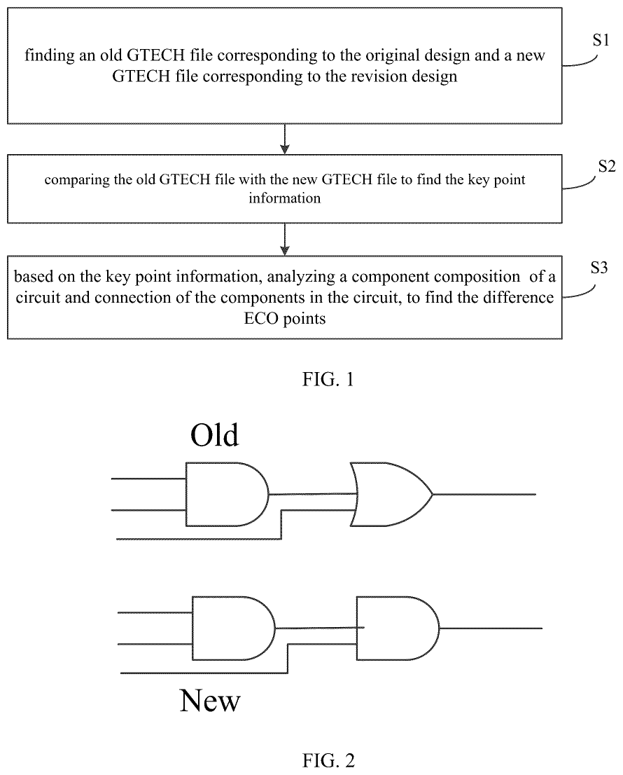

As shown in FIG. 1, the present embodiment provides a method of obtaining ECO points based on a comparison of design files, and the detailed steps are as follows:
Step S1, finding an old GTECH file corresponding to the original design and a new GTECH file corresponding to the revision design.

A computer with sufficient computing power, a computer equipped with an Intel Core i7 multi-core processor and 300 GB of RAM are used. Two files are stored on the computer's hard disk, and an ECO software (EasylogicECO) from Easy-Logic Technology is used to compare the two files. This tool helps us to find out the changes in the types of components and connections contained therein.
Step S2, comparing the old GTECH file with the new GTECH file to find the key point information.

Based on the component, structures of the old GTECH file and the new GTECH file are analyzed, to find types, numbers and connection relationships of components contained in the old GTECH file and the new GTECH file respectively. The type, number and connection relationship of each component in the old GTECH file and the new GTECH file are compared to see whether they are changed, and when one thereof is not the same in the old GTECH file and the new GTECH file, then it is determined that the component is changed. The changed components are marked as key point information.

Based on the logic, whether logical functionality implemented in the old GTECH file and the new GTECH file are consistent is determined, a part of the logical functionality that is changed is marked as the key point information The key point information includes at least: a key component added or deleted, a component whose parameter change affects timing or power consumption, and the part of the logical functionality that is changed. The comparing whether the type, number and connection relationship of the components contained in the old GTECH file and the new GTECH file is changed includes determining whether the type of each component in the old GTECH file and the new GTECH file is the same, whether there are new or deleted types of components, or whether any types of components are replaced; and determining whether the number of components of the same type in the old GTECH file and the new GTECH file are the same. Any increase or decrease in the number is considered to be a change.

The structures of the old GTECH file and the new GTECH file of revision design are analyzed, the structures of the two files are parsed, the type and connection relationships of the component contained therein are extracted, and this information is stored in the internal database of the EasylogicECO tool.

The types, numbers, parameters, attributes and connection relationships of each component contained in the two files are compared to determine whether there are any changes, a C++ programme is used to traverse the internal databases corresponding to old GTECH and new GTECH, and compare the information contained therein. If the type and number of a component is changed, it will be marked as the key point information.

Whether the logical functionality of the new GTECH file of the revision design is consistent with the logical functionality of the old GTECH file of the original design is analyzed, the EasylogicECO is used to analyze the logical functionality of these two files, if the logical functionality is changed, it will be marked as the key point information.
Step S3, based on the key point information, analyzing a component composition of a circuit and connection of the components in the circuit, to find the difference ECO points.

Functions of the circuits of the original design and the revision design based on the key point information are compared; overall circuit architectures and functional description of the original design and the revision design are analyzed; a connection relationship and a signal flow of each component in the original design and the revision design are compared; whether there are new or deleted component connections and changes in the connection relationships is checked; and the key point information where there are differences is marked as the difference ECO points.

The consistency of the logical functionality, including at least the signal flow and the interface compatibility, implemented in the old GTECH file and the new GTECH file is compared to check whether the two files are functionally equivalent. The check of the interface compatibility refers to verifying whether the interfaces in the old GTECH file and the new GTECH file are compatible to ensure that there will be no problem in connection with the other modules.

The EasylogicECO is used to compare the functionality of the circuits in the two designs and if any differences are found, they will be marked as ECO points.

It should be noted that the GTECH used in this implementation retains the same hierarchical structure as the original RTL without any logic optimization, so the difference between the original and the revision GTECH is less than the difference between the original and the revision synthesis netlist. The difference points (i.e. ECO points) can be found by simply comparing the circuit topology (the connection relationship of various circuit units), while the synthesis netlist can only be compared and analyzed at the logical functionality because the topology of the circuit has been changed after the optimization, so it requires commercial LEC tools to make a longer comparison, and the GTECH RTL describes the chip circuit from the logical functionality, while the netlist reflects the specific structure of the circuit (composition and connection relationship), so the comparison between natural netlists is more intuitive and faster, and therefore it is faster and easier to find the ECO points through GTECH comparison than RTL direct comparison.

The original and revised GTECH files are compared to find key points (Blackbox, Primary Inputs, Primary Output, DFF). Because GTECH has not been optimized by synthesis tools, when matching, it needn't to consider sequential optimizations such as constant propagation, register merging, INV push, which greatly improves the accuracy and speed of matching. And it is because GTECH is not optimized, many modules in the original and modified GTECH are unchanged, and the implementation structure therein is the same, so the analysis of logical functionality conducted by the LEC engine can be replaced by structural analysis, i.e., the analysis of the component composition of the circuit and connection of the component, which can improve the speed of operation.

Through experimental measurements, this implementation of the method of obtaining ECO points based on GTECH usually takes only ten minutes to complete, which greatly saves time and labour costs compared to traditional methods.

The specific embodiments described above, the purpose, technical solutions and beneficial effects of the present application are further described in detail, it should be understood that the above is only a specific embodiment of the present application, and is not intended to limit the scope of the present application, and any modifications, equivalent substitutions, improvements, etc. made within the spirit of the present application shall be included in the scope of the present application.

What is claimed is:

1. A method for obtaining an engineering change order (ECO) point based on a comparison of design files, for finding difference ECO points between a revision design and an original design in a chip design, wherein the method uses a generic technology (GTECH) file for comparison without using a logic equivalence check (LEC) tool;
the method comprises:
Step S1, finding an old GTECH file corresponding to the original design and a new GTECH file corresponding to the revision design;
Step S2, comparing the old GTECH file and the new GTECH file to find key point information; and
Step S3, based on the key point information, analyzing a component composition of a circuit and connection of components in the circuit, to find the difference ECO points.

2. The method for obtaining the ECO point based on the comparison of the design file according to claim 1, wherein in the step S2, the comparing the old GTECH file and the new GTECH file comprises:
comparing based on a component and a logic, respectively, to find the key point information;
based on the component, analyzing structures of the old GTECH file and the new GTECH file, and finding types, numbers and connection relationships of components contained in the old GTECH file and the new GTECH file respectively;
comparing the type, number and connection relationship of each component in the old GTECH file and the new GTECH file to see whether they are changed, and when one thereof is not the same in the old GTECH file and the new GTECH file, then it is determined that the component is changed;
marking the changed component as the key point information; and
based on the logic, determining whether logical functionality implemented in the old GTECH file and the new GTECH file are consistent, marking a part of the logical functionality that is changed as the key point information.

3. The method for obtaining the ECO point based on the comparison of the design file according to claim 2, wherein the key point information at least comprises a key component added or deleted, a component whose parameter change affects timing or power consumption, and the part of the logical functionality that is changed.

4. The method for obtaining the ECO point based on the comparison of the design file according to claim 3, wherein the comparing the type, number and connection relationship of each component in the old GTECH file and the new GTECH file to see whether they are changed comprises:
determining whether the type of each component in the old GTECH file and the new GTECH file is the same, whether there are new or deleted types of components, or whether any types of components are replaced; and
determining whether the number of components of the same type in the old GTECH file and the new GTECH file are the same, wherein any increase or decrease in the number is considered to be a change.

5. The method for obtaining the ECO point based on the comparison of the design file according to claim 1, wherein in the step S3, the analyzing the component composition of the circuit and connection of the component in the circuit comprises:
comparing functions of the circuits of the original design and the revision design based on the key point information;
analyzing overall circuit architectures and functional description of the original design and the revision design;
comparing a connection relationship and a signal flow of each component in the original design and the revision design;
checking whether there are new or deleted component connections and changes in the connection relationships; and
marking the key point information where there are differences as the difference ECO points.

6. The method for obtaining the ECO point based on the comparison of the design file according to claim 4, wherein the comparing a consistency of logical functionality implemented in the old GTECH file and the new GTECH file is to check whether the old GTECH file and the new GTECH file are functionally equivalent, at least comprising checks of the signal flow and interface compatibility;
the check of the signal flow refers to check whether a flow path of signals in the old GTECH file and the new GTECH file are the same, comprising a transmission, processing and output of the signals; and
the check of the interface compatibility refers to verify that interfaces in the old GTECH file and the new GTECH file are compatible to ensure that there are no problems with connections to other modules.
